(19) United States
(12) Patent Application Publication
(10) Pub. No.: US 2016/0150678 A1
(43) Pub. Date: May 26, 2016

(54) Silicon Cooling Plate With An Integrated PCB

(71) Applicant: Gerald Ho Kim, Fallbrook, CA (US)

(72) Inventor: Gerald Ho Kim, Fallbrook, CA (US)

(21) Appl. No.: 14/948,368

(22) Filed: Nov. 22, 2015

Related U.S. Application Data
(60) Provisional application No. 62/083,190, filed on Nov. 22, 2014.

(51) Int. Cl. H05K 7/20; H05K 7/02

(52) U.S. Cl. CPC H05K 7/20254; H05K 7/20272; H05K 7/023

(57) ABSTRACT

Examples of a silicon cold plate with an integrated PCB are described. An apparatus may include a silicon plate, one or more electrical and thermal connections, and a heat-generating device. The silicon plate may include a first side and a second side opposite the first side, a plurality of edges between the first side and the second side, one or more internal coolant flow channels therein, one or more coolant inlet ports disposed on one or more of the edges and configured to allow a coolant to flow into the one or more internal coolant flow channels, and one or more coolant outlet ports disposed on one or more of the edges and configured to allow the coolant to flow out of the one or more internal coolant flow channels. The one or more electrical and thermal connections may be disposed on the first side of the silicon plate. The heat-generating device may be disposed on the one or more electrical and thermal connections.

CROSS REFERENCE TO RELATED PATENT APPLICATION

The present disclosure claims the priority benefit of U.S. Provisional Patent Application No. 62/083,190, filed on 22 Nov. 2014, which is incorporated by reference in its entirety.

### TECHNICAL FIELD

The present disclosure generally relates to the field of transfer of thermal energy and, more particularly, to a silicon cooling plate with an integrated printed circuit board.

### BACKGROUND

Unless otherwise indicated herein, the approaches described in this section are not prior art to the claims in this application and are not admitted to be prior art by inclusion in this section.

Large heat generating integrated circuit (IC) chips are typically mounted on a printed circuit board (PCB) or IC interposer by a ball-bumped or pin connector. However, there is usually a limitation on the amount of thermal energy, or heat, dissipated by the IC chips and into the PCB or surroundings. In order to dissipate a large amount of heat (e.g., greater than 10 watt/cm²), an extra air-cooled heat sink is often attached to a top side of the IC chips where there are no pads, ball-bumps or pins. However, for a power density exceeding 100 watt/cm², a liquid cooling solution may be necessary in place of the air cooling solution in order to lower a junction temperature of bare-die chips.

Conventionally, cooling plates are made with a metal material, such as copper, aluminum or copper/aluminum hybrid, to be mounted on the opposite side of the ball-bumps or the side of the fin electrical connectors. Typically heat is generated by IC chips on the side at which all ball-bumps or fins are located. The heat needs to be removed from the ball-bumps or fin side of the IC chips in order to be dissipated effectively. However, it often becomes incredibly difficult to attach a cooling plate on the ball-bumps or fin side of IC chips where both electrical connection and thermal connection are maximized.

### SUMMARY

The following summary is illustrative only and is not intended to be limiting in any way. That is, the following summary is provided to introduce concepts relating to a heat sink for thermal management in an electronic apparatus. Select embodiments of the novel and non-obvious technique are further described below in the detailed description. Thus, the following summary is not intended to identify essential features of the claimed subject matter, nor is it intended for use in determining the scope of the claimed subject matter.

In one aspect, an apparatus may include a silicon plate, one or more electrical and thermal connections, and a heat-generating device. The silicon plate may include a first side and a second side opposite the first side, a plurality of edges between the first side and the second side, one or more internal coolant flow channels therein, one or more coolant inlet ports disposed on one or more of the edges and configured to allow a coolant to flow into the one or more internal coolant flow channels, and one or more coolant outlet ports disposed on one or more of the edges and configured to allow the coolant to flow out of the one or more internal coolant flow channels. The one or more electrical and thermal connections may be disposed on the first side of the silicon plate. The heat-generating device may be disposed on the one or more electrical and thermal connections.

In another aspect, an apparatus may include a first module and a second module. The first module may include a first silicon plate, one or more first electrical and thermal connections, and a first heat-generating device. The first silicon plate may include a first side and a second side opposite the first side, a plurality of edges between the first side and the second side, one or more internal coolant flow channels therein, one or more coolant inlet ports disposed on one or more of the edges and configured to allow a coolant to flow into the one or more internal coolant flow channels, and one or more coolant outlet ports disposed on one or more of the edges and configured to allow the coolant to flow out of the one or more internal coolant flow channels. The one or more first electrical and thermal connections may be disposed on the first side of the first silicon plate. The first heat-generating device may be disposed on the one or more first electrical and thermal connections. The second module may include a second silicon plate, one or more second electrical and thermal connections, and a second heat-generating device. The second silicon plate may include a first side and a second side opposite the first side, a plurality of edges between the first side and the second side, one or more internal coolant flow channels therein, one or more coolant inlet ports disposed on one or more of the edges and configured to allow the coolant to flow into the one or more internal coolant flow channels, and one or more coolant outlet ports disposed on one or more of the edges and configured to allow the coolant to flow out of the one or more internal coolant flow channels. The one or more second electrical and thermal connections may be disposed on the first side of the second silicon plate. The second heat-generating device may be disposed on the one or more second electrical and thermal connections.

### BRIEF DESCRIPTION OF THE DRAWINGS

The accompanying drawings are included to provide a further understanding of the disclosure, and are incorporated in and constitute a part of the present disclosure. The drawings illustrate embodiments of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 is a top perspective view of an apparatus in accordance with an embodiment of the present disclosure.

FIG. 2 is a top perspective view of an apparatus in accordance with another embodiment of the present disclosure.

FIG. 3A is a top perspective view of an apparatus in accordance with another embodiment of the present disclosure.

FIG. 3B is a side view of the apparatus shown in FIG. 3A.

FIG. 3C is a bottom perspective view of the apparatus shown in FIG. 3A.

FIG. 3D is an exploded view of the apparatus shown in FIGS. 3A-3C.

FIG. 4A is a top perspective view of an apparatus in accordance with another embodiment of the present disclosure.

FIG. 4B is an exploded view of the apparatus shown in FIG. 4A.

FIG. 5 is a diagram of a system incorporating the apparatus shown in FIGS. 4A and 4B.

FIG. 6 is a diagram of an apparatus in accordance with an embodiment of the present disclosure.

FIG. 7 is a diagram of a system incorporating the apparatus shown in FIG. 6.

### DETAILED DESCRIPTION OF PREFERRED EMBODIMENTS

### Overview

To develop a better cooling plate, a single-crystal silicon is used to build a compact module with flow channel for a fluid (e.g., cooling liquid) to flow therein to maximize thermal performance of the cooling plate. The silicon cooling plate adds a few advantage of building a micron-size liquid-cooled module compared to those built with metal cooling plates. Moreover, the use of silicon for cooling plates allows advantages such as bulk-volume manufacturing of using semiconductor fabrication processes, building of a micron-size structure with a lighter density than most of those built with metal cooling plates, and the silicon cooling plate being chemically inert to most types of coolant. To date, the hybrid construction of a single structure of a liquid-cooled module with silicon cooling plate and PCB interconnect has not been developed due a lack of compact form factor and cost-effective cooling plate design.

Silicon cooling plate has a large heat dissipation capacity using mini-channel design that reduces a high coolant pressure drop between inlet and outlet port compared to a micro-channel design. Due to a large heat removing capability, both sides of a silicon cooling plate can be used to mount hot IC chips. The IC chips, mounted on both sides of the silicon cooling plate, can be electrically connected to one another by a through-via hole design. For example, one side of the silicon cooling plate can be attached with a processor chip and the other side can be attached with a graphics-processing chip. Both chips can be connected by silicon through-via holes to electrically connect to each other. In this case the through-via holes can function as an electrical connection path as well as a thermal dissipation path. The silicon cooling plate can act as a mini-motherboard to mount not only a processor and a graphics-processing chip, but also one or more other IC chips such as memory chip, communication chip, flash memory chip, imaging chip, sensor chip and many other types of IC chips to function as a high-performance server or computer.

An IC chip mounted on a silicon cooling plate may be electrically connected to other IC chips on the PCB through electrical pad between the silicon cooling plate and the IC chips. Also, a thermal via in the IC chip may be used to dissipate heat from the IC chip into the silicon cooling plate. The majority of heat generated in the IC chip will be dissipated into the coolant through the thermal pad(s) in the IC chip. Moreover, some of the electrical pad(s) connected to the PCB may be used to remove any heat spread in the PCB. The silicon cooling plate can thus remove heat from the hot IC chips and PCB.

Embodiments of the silicon cold plate mounted with PCB may have easy connect ports along with an electrical inter-connect port. The silicon cold plate may provide a compact and easy electrical and thermal interconnect to a back-plane where it provides constant cooling and electrical connection to other modules. The electrical port and thermal inter-connection ports may be in the same plane of the hybrid cooling module. Multiple ones of the hybrid cooling module may be stacked for better compactness and close interconnect for a fast electrical processing.

Typically, edges of a silicon cold plate may be fabricated to be square corners due to wafer dicing process to cut the silicon cold plate. Embodiments of the present disclosure are made with etching process to cut some or all of the edges of a silicon cold plate so that some or all of the edges are shaped like a tapered-edge, or beveled, structure. The silicon cold plate may be mounted to a PCB, with the silicon cold plate and PCB having different thermal expansion coefficients. During thermal cycling, the silicon cold plate may experience moderate thermal stress since the silicon cold plate may be soldered to the PCB. It is important to have one or more smooth edges to prevent silicon structure failure. Most dicing processes tend to create small micro-cracks along a given diced edge and a crack may propagate as the silicon cold plate experiences tensile and compressive forces caused by thermal stress during each thermal cycle.

Thermal stress may or may not be a significant issue for certain applications, such as computer server circuit, home computer or high-power light-emitting diode (LED) lighting system, due to their controlled environment that tend to result in moderate temperature cycles. However, other applications, such as space satellite, telecommunication control tower electronics, automobile computer system or aviation electronics, tend to go through a large temperature swing during operation. This will require a far better control on the shape of the edges of the silicon cold plate in order to minimize failure due to micro-crack propagation.

Compared to conventional metal or ceramic cold plates, a novel and distinctive feature of a silicon cold plate in accordance with the present disclosure is that the silicon cold plate has hexagonal shape for its inlet and outlet ports. Due to the single-crystal structure of silicon face orientation of <100> plane, the coolant channel has a semi-hexagonal shape, and may be bonded by silicon-to-silicon bonding method of silicon fusion bonding, glass frit bonding, gold eutectic bonding, metal soldering after depositing metal layer. The aforementioned bonding methods will yield a hexagonal shape for the coolant channel(s) as well as for the inlet port(s) and outlet port(s). The hexagonal shape of the cooling channel(s) in the silicon cold plate tends to provide better fluid dynamics and thermal transfer behaviors.

### Illustrative Implementations

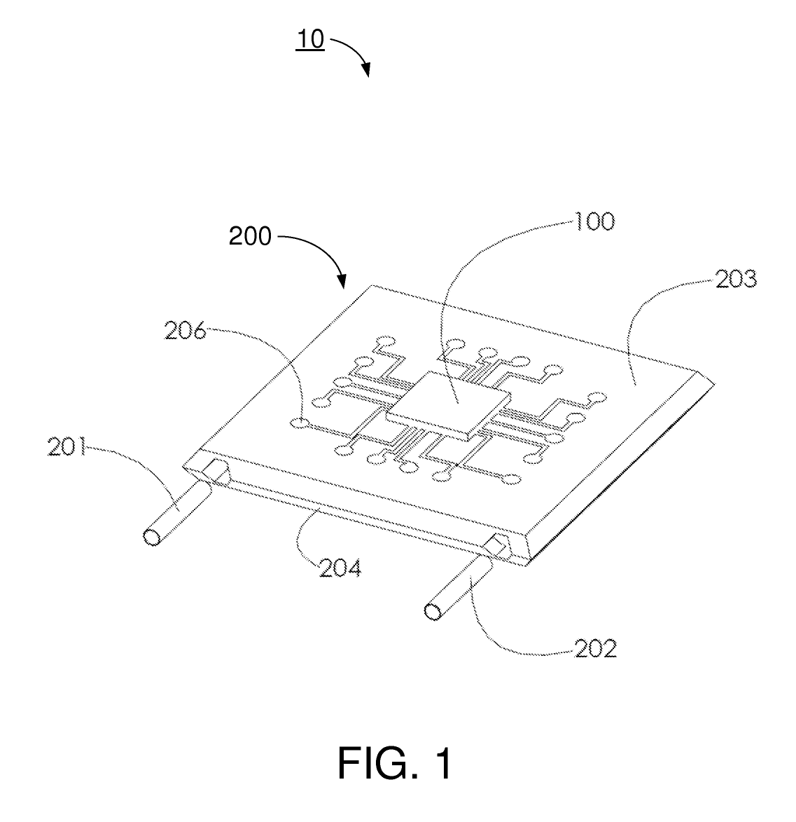

FIG. 1 is a top perspective view of an apparatus 10 in accordance with an embodiment of the present disclosure. As shown in FIG. 1, apparatus 10 may include a silicon cold plate 200 which may include a silicon-based first half plate 203 and a silicon-based second half plate 204 coupled or bonded to each other or otherwise assembled together. Specifically, each of first half plate 203 and second half plate 204 may respectively have a mating side and a carry side opposite the mating side, with multiple edges (e.g., four edges) between the carry side and mating side thereof. At least one edge of the multiple edges of each of first half plate 203 and second half plate 204 may be a tapered edge. In some embodiments, each edge of the multiple edges of each of first half plate 203 and second half plate 204 may be a tapered edge. That is, at least one edge of the multiple edges of first half plate 203 and second half plate 204 may be a beveled edge. When first half plate 203 and second half plate 204 are bonded together to form the sealed silicon cold plate 200, with the mating side of first half plate 203 and the mating side of second half plate 204 facing each other, the carry side of first half plate 203 and the carry side of second half plate 204 become the two primary exterior sides of silicon cold plate 200 with multiple (e.g., four) edges between the two exterior sides thereof. Each of the mating side of first half plate 203 and the mating side of second half plate 204 has one or more recesses corresponding to one another such that, when first half plate 203 and second half plate 204 are bonded together, one or more internal coolant flow channels are formed in silicon cold plate 200 (e.g., for liquid or gas to flow therein as a coolant for heat transfer) by the one or more recesses on the mating side of each of first half plate 203 and second half plate 204.

Moreover, one or more polygonal-shaped coolant inlet ports and one or more polygonal-shaped coolant outlet ports are formed on one or more edges of silicon cold plate 200 by the one or more recesses on the mating side of each of first half plate 203 and second half plate 204. In some embodiments, the one or more coolant inlet ports may be hexagonal shaped, and the one or more coolant outlet ports may also be hexagonal shaped. Referring to FIG. 1, the edge of silicon cold plate 200 that faces the reader includes a coolant inlet port and a coolant outlet port. A coolant outlet connector 201 may be accommodated by, received in, mounted on or otherwise coupled to the coolant outlet port. A coolant inlet connector 202 may be accommodated by, received in, mounted on or otherwise coupled to the coolant inlet port. In various other embodiments in accordance with the present disclosure (not shown), one or more other edges of silicon cold plate 200 may additionally include one or more coolant inlet ports and/or one or more coolant outlet ports.

In the example shown in FIG. 1, the carry side of first half plate 203 includes electrical and thermal patterns or connections 206. A heat-generating device 100 may be electrically and thermally bonded to and disposed on electrical and thermal patterns or connections 206 with pads, ball-bumps or pins of heat-generating device 100 (not shown) in contact and connected to electrical and thermal patterns or connections 206. Heat-generating device 100 may be an IC chip with high thermal flux. Electrical and thermal patterns or connections 206 are electrically and thermally conductive, and may be formed on the carry side of first half plate 203 by electroplating or metal deposition. Heat-generating device 100, as an IC chip or an electronic device, may receive electrical power through as well as dissipate heat through electrical and thermal patterns or connections 206.

This compact design may be useful in satellites (e.g., CubeSat) as it will be better to have a 100 mm×100 mm silicon cold plate without PCB. Apparatus 10 may be used individually or stacked (multiple ones thereof) for standalone circuit system.

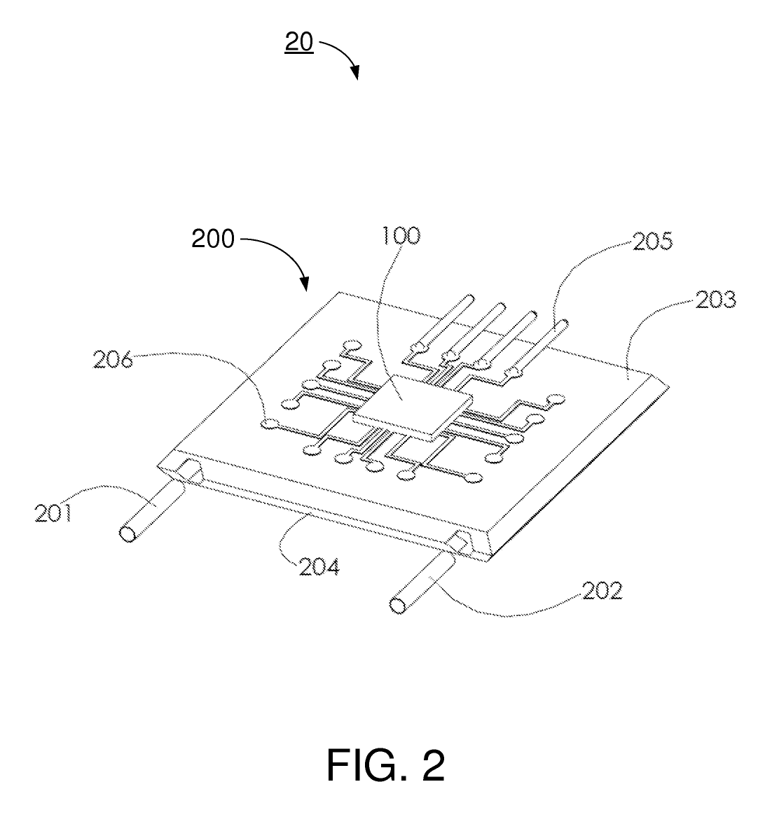

FIG. 2 is a top perspective view of an apparatus 20 in accordance with another embodiment of the present disclosure. Apparatus 20 may be similar to apparatus 10 in that apparatus 20 may include certain components that are similar or identical to corresponding components in apparatus 10. As shown in FIG. 2, apparatus 20 may include a silicon cold plate 200 which may include a silicon-based first half plate 203 and a silicon-based second half plate 204 coupled or bonded to each other or otherwise assembled together. Specifically, each of first half plate 203 and second half plate 204 may respectively have a mating side and a carry side opposite the mating side, with multiple edges (e.g., four edges) between the carry side and mating side thereof. At least one edge of the multiple edges of each of first half plate 203 and second half plate 204 may be a tapered edge. In some embodiments, each edge of the multiple edges of each of first half plate 203 and second half plate 204 may be a tapered edge. That is, at least one edge of the multiple edges of first half plate 203 and second half plate 204 may be a beveled edge. When first half plate 203 and second half plate 204 are bonded together to form the sealed silicon cold plate 200, with the mating side of first half plate 203 and the mating side of second half plate 204 facing each other, the carry side of first half plate 203 and the carry side of second half plate 204 become the two primary exterior sides of silicon cold plate 200 with multiple (e.g., four) edges between the two exterior sides thereof. Each of the mating side of first half plate 203 and the mating side of second half plate 204 has one or more recesses corresponding to one another such that, when first half plate 203 and second half plate 204 are bonded together, one or more internal coolant flow channels are formed in silicon cold plate 200 (e.g., for liquid or gas to flow therein as a coolant for heat transfer) by the one or more recesses on the mating side of each of first half plate 203 and second half plate 204.

Moreover, one or more polygonal-shaped coolant inlet ports and one or more polygonal-shaped coolant outlet ports are formed on one or more edges of silicon cold plate 200 by the one or more recesses on the mating side of each of first half plate 203 and second half plate 204. In some embodiments, the one or more coolant inlet ports may be hexagonal shaped, and the one or more coolant outlet ports may also be hexagonal shaped. Referring to FIG. 2, one edge of silicon cold plate 200 may include a coolant inlet port and a coolant outlet port. A coolant outlet connector 201 may be accommodated by, received in, mounted on or otherwise coupled to the coolant outlet port. A coolant inlet connector 202 may be accommodated by, received in, mounted on or otherwise coupled to the coolant inlet port. In various other embodiments in accordance with the present disclosure (not shown), one or more other edges of silicon cold plate 200 may additionally include one or more coolant inlet ports and/or one or more coolant outlet ports.

In the example shown in FIG. 2, the carry side of first half plate 203 includes electrical and thermal patterns or connections 206. A heat-generating device 100 may be electrically and thermally bonded to and disposed on electrical and thermal patterns or connections 206 with pads, ball-bumps or pins of heat-generating device 100 (not shown) in contact and connected to electrical and thermal patterns or connections 206. Heat-generating device 100 may be an IC chip with high thermal flux. Electrical and thermal patterns or connections 206 are electrically and thermally conductive, and may be formed on the carry side of first half plate 203 by electroplating or metal deposition. Heat-generating device 100, as an IC chip or an electronic device, may receive electrical power through as well as dissipate heat through electrical and thermal patterns or connections 206. Different from apparatus 10, apparatus 20 may also include one or more pins or connections 205 electrically and thermally connected to electrical and thermal patterns or connections 206. The one or more pins or connections 205 are configured to accommodate off-substrate electrical connections directly to the carry side of silicon cold plate 200 (e.g., to accommodate an electrical connection between heat-generating device 100 and an external device).

This compact design may be useful in satellites (e.g., CubeSat) as it will be better to have a 100 mm×100 mm silicon cold plate without PCB. Apparatus 20 may be used individually or stacked (multiple ones thereof) for standalone circuit system.

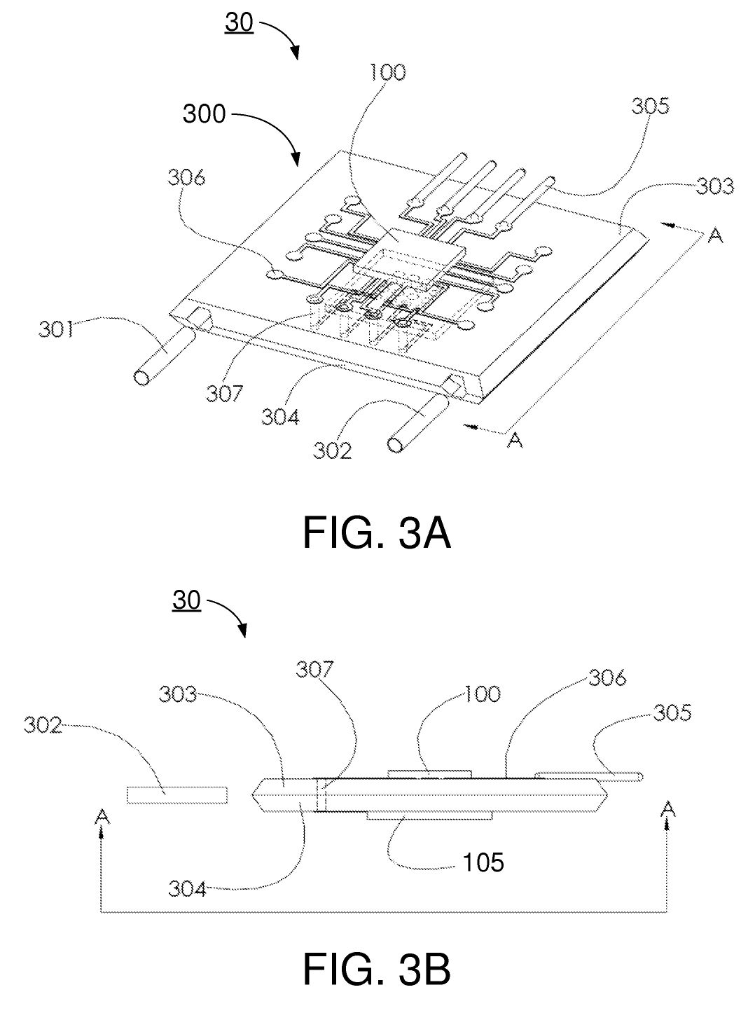

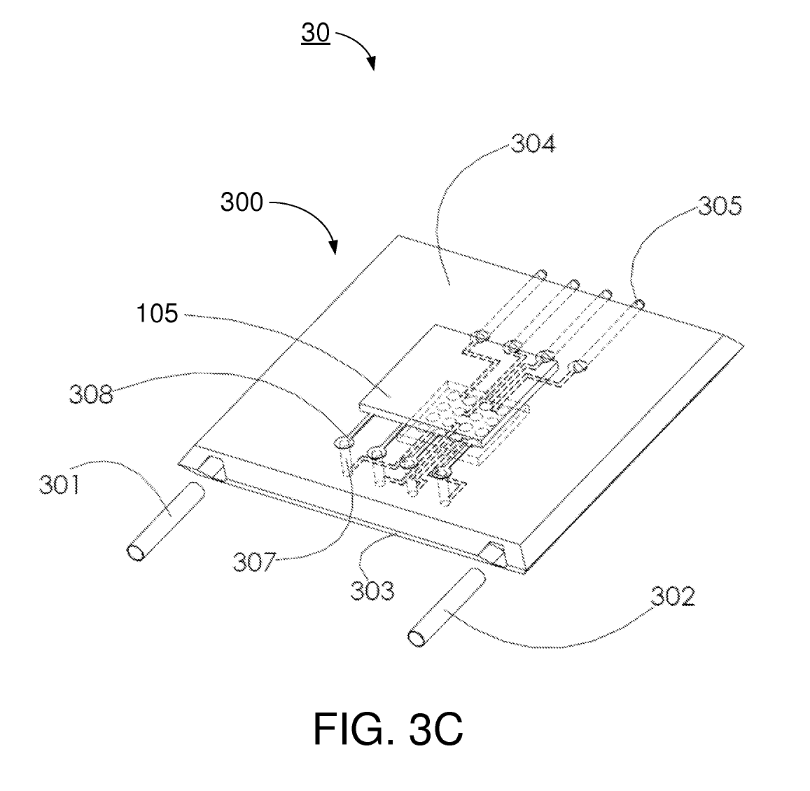

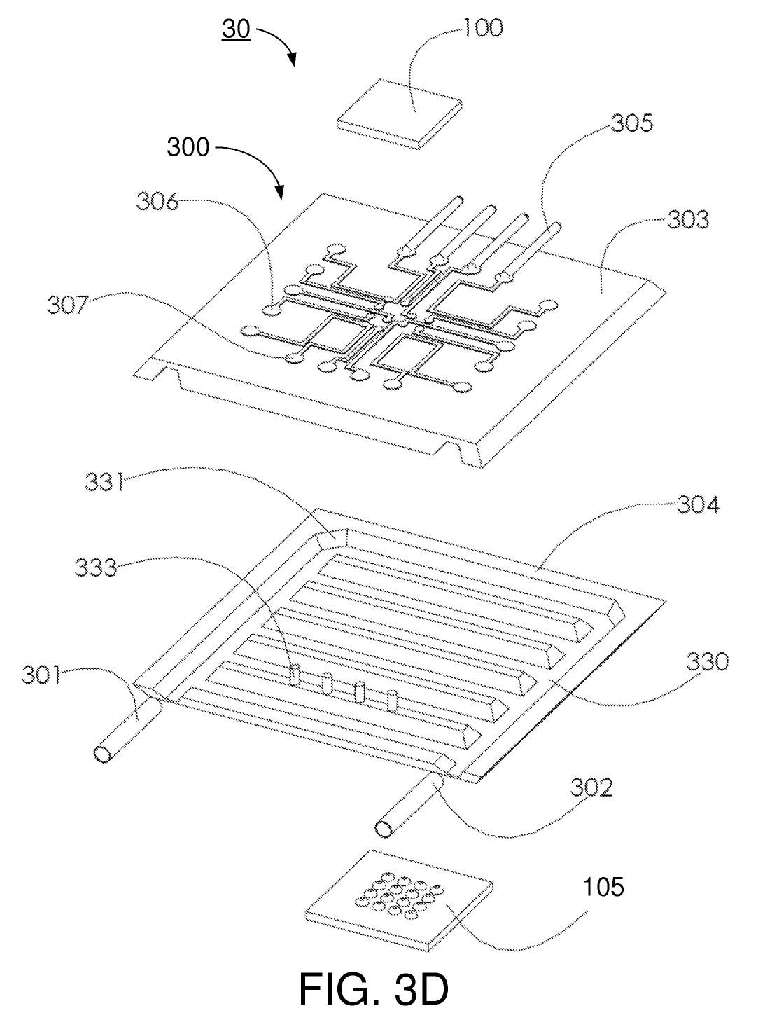

FIGS. 3A-3D illustrate an apparatus 30 in accordance with another embodiment of the present disclosure. As shown in FIGS. 3A-3D, apparatus 30 may include a silicon cold plate 300 which may include a silicon-based first half plate 303 and a silicon-based second half plate 304 coupled or bonded to each other or otherwise assembled together. Specifically, each of first half plate 303 and second half plate 304 may respectively have a mating side and a carry side opposite the mating side, with multiple edges (e.g., four edges) between the carry side and mating side thereof. At least one edge of the multiple edges of each of first half plate 303 and second half plate 304 may be a tapered edge. In some embodiments, each edge of the multiple edges of each of first half plate 303 and second half plate 304 may be a tapered edge. That is, at least one edge of the multiple edges of first half plate 303 and second half plate 304 may be a beveled edge. When first half plate 303 and second half plate 304 are bonded together to form the sealed silicon cold plate 300, with the mating side of first half plate 303 and the mating side of second half plate 304 facing each other, the carry side of first half plate 303 and the carry side of second half plate 304 become the two primary exterior sides of silicon cold plate 300 with multiple (e.g., four) edges between the two exterior sides thereof. Each of the mating side of first half plate 303 and the mating side of second half plate 304 has one or more recesses corresponding to one another such that, when first half plate 303 and second half plate 304 are bonded together, one or more internal coolant flow channels are formed in silicon cold plate 300 (e.g., for liquid or gas to flow therein as a coolant for heat transfer) by the one or more recesses on the mating side of each of first half plate 303 and second half plate 304.

Moreover, one or more polygonal-shaped coolant inlet ports and one or more polygonal-shaped coolant outlet ports are formed on one or more edges of silicon cold plate 300 by the one or more recesses on the mating side of each of first half plate 303 and second half plate 304. In some embodiments, the one or more coolant inlet ports may be hexagonal shaped, and the one or more coolant outlet ports may also be hexagonal shaped. Referring to FIGS. 3A-3D, one edge of silicon cold plate 300 may include both a coolant inlet port and a coolant outlet port. A coolant inlet connector 301 may be accommodated by, received in, mounted on or otherwise coupled to the coolant inlet port. A coolant outlet connector 302 may be accommodated by, received in, mounted on or otherwise coupled to the coolant inlet port. In various other embodiments in accordance with the present disclosure (not shown), one or more other edges of silicon cold plate 300 may additionally include one or more coolant inlet ports and/or one or more coolant outlet ports. Referring to FIG. 3D, in which the mating side of second half plate 304 is visible, the mating side of second half plate 304 includes multiple etched silicon coolant channels 330 and coolant flow directors 331, with multiple pillars 333 of an electrically and thermally conductive material filled in vias 307 that traverse through first half plate 303 and second half plate 304. Also in the example shown in FIG. 3D, second heat-generating device 105 includes pads, ball-bumps or pins on second heat-generating device that are soldered to the carry side of second half plate 304.

In the example shown in FIGS. 3A-3D, the carry side of first half plate 303 includes electrical and thermal patterns or connections 306, and the carry side of second half plate 304 includes electrical and thermal patterns or connections 308. Electrical and thermal patterns or connections 306 and electrical and thermal patterns or connections 308, on opposite sides of cold silicon plate 300, may be electrically and thermally connected to each other by one or more substrate vias 307. The one or more vias 307 are filled with or contain one or more pillars 333 of an electrically and thermally conductive material to provide path(s) of electrical and thermal conduction between electrical and thermal patterns or connections 306 and electrical and thermal patterns or connections 308. A first heat-generating device 100 may be electrically and thermally bonded to and disposed on electrical and thermal patterns or connections 206 with pads, ball-bumps or pins of first heat-generating device 100 (not shown) in contact and connected to electrical and thermal patterns or connections 306. First heat-generating device 100 may be an IC chip with high thermal flux. Electrical and thermal patterns or connections 306 are electrically and thermally conductive, and may be formed on the carry side of first half plate 303 by electroplating or metal deposition. First heat-generating device 100, as an IC chip or an electronic device, may receive electrical power through as well as dissipate heat through electrical and thermal patterns or connections 306. Similarly, a second heat-generating device 105 may be electrically and thermally bonded to and disposed on electrical and thermal patterns or connections 308 with pads, ball-bumps or pins of second heat-generating device 105 (not shown) in contact and connected to electrical and thermal patterns or connections 308. Second heat-generating device 105 may be an IC chip with high thermal flux. Electrical and thermal patterns or connections 308 are electrically and thermally conductive, and may be formed on the carry side of second half plate 304 by electroplating or metal deposition. Second heat-generating device 105, as an IC chip or an electronic device, may receive electrical power through as well as dissipate heat through electrical and thermal patterns or connections 308.

In the example shown in FIGS. 3A-3D, apparatus 30 may also include one or more pins or connections 305 electrically and thermally connected to electrical and thermal patterns or connections 306. The one or more pins or connections 305 are configured to accommodate off-substrate electrical connections directly to the carry side of silicon cold plate 300. Alternatively or alternatively, although not shown in the figures, the one or more pins or connections 305 may be electrically and thermally connected to electrical and thermal patterns or connections 308. Thus, first heat-generating device 100 may be electrically connected to an external device through electrical and thermal patterns or connections 306 and the one or more pins or connections 305, and second heat-generating device 105 may be electrically connected to the same or different external device through electrical and thermal patterns or connections 308, the one or more vias 307, electrical and thermal patterns or connections 306 (at least a portion thereof) and the one or more pins or connections 305.

This compact design may be useful in satellites (e.g., CubeSat) as it will be better to have a 100 mm×100 mm silicon cold plate without PCB. Apparatus 30 may be used individually or stacked (multiple ones thereof) for standalone circuit system.

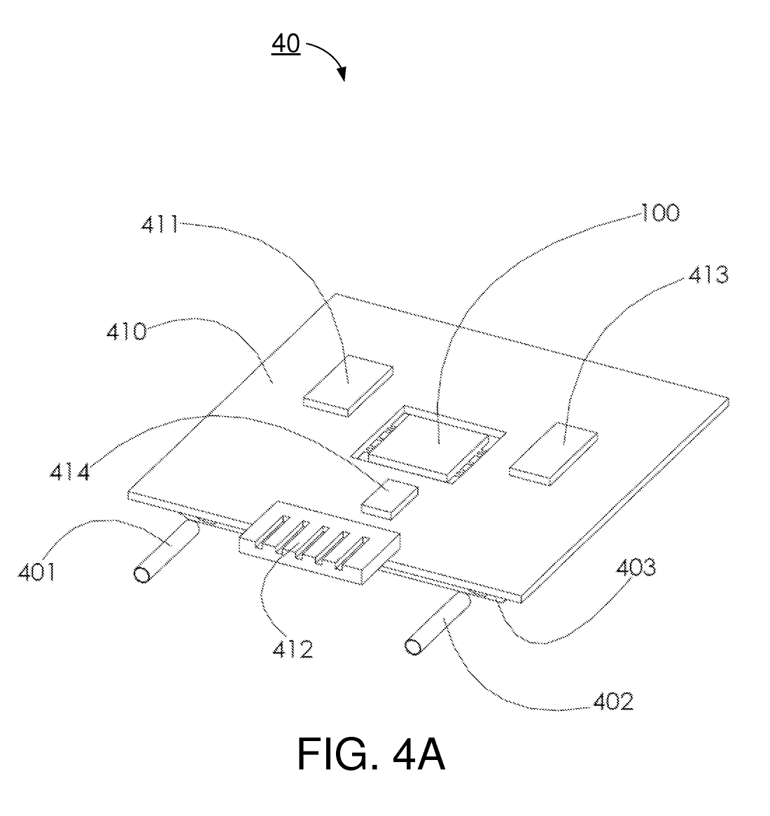

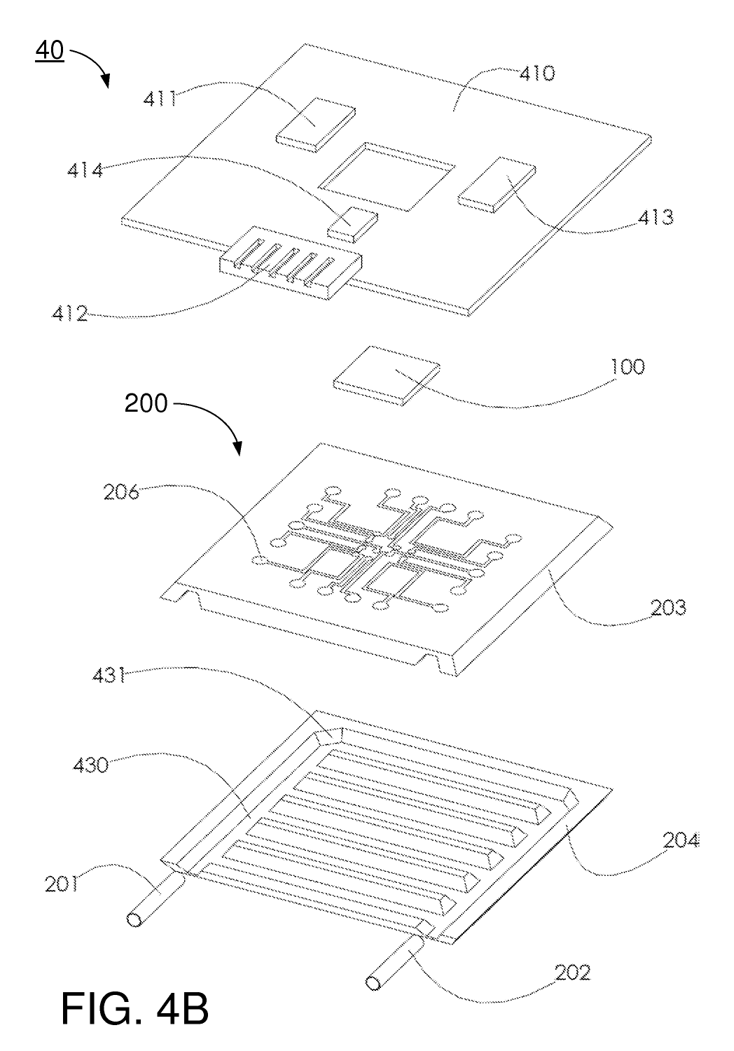

FIGS. 4A and 4B illustrate an apparatus 40 in accordance with another embodiment of the present disclosure. As shown in FIGS. 4A and 4B, apparatus 40 may include certain components that are similar or identical to corresponding components of apparatus 10. As shown in FIGS. 4A and 4B, apparatus 40 may include a silicon cold plate 200 which may include a silicon-based first half plate 203 and a silicon-based second half plate 204 coupled or bonded to each other or otherwise assembled together. Specifically, each of first half plate 203 and second half plate 204 may respectively have a mating side and a carry side opposite the mating side, with multiple edges (e.g., four edges) between the carry side and mating side thereof. At least one edge of the multiple edges of each of first half plate 203 and second half plate 204 may be a tapered edge. In some embodiments, each edge of the multiple edges of each of first half plate 203 and second half plate 204 may be a tapered edge. That is, at least one edge of the multiple edges of first half plate 203 and second half plate 204 may be a beveled edge. When first half plate 203 and second half plate 204 are bonded together to form the sealed silicon cold plate 200, with the mating side of first half plate 203 and the mating side of second half plate 204 facing each other, the carry side of first half plate 203 and the carry side of second half plate 204 become the two primary exterior sides of silicon cold plate 200 with multiple (e.g., four) edges between the two exterior sides thereof. Each of the mating side of first half plate 203 and the mating side of second half plate 204 has one or more recesses corresponding to one another such that, when first half plate 203 and second half plate 204 are bonded together, one or more internal coolant flow channels are formed in silicon cold plate 200 (e.g., for liquid or gas to flow therein as a coolant for heat transfer) by the one or more recesses on the mating side of each of first half plate 203 and second half plate 204.

Moreover, one or more polygonal-shaped coolant inlet ports and one or more polygonal-shaped coolant outlet ports are formed on one or more edges of silicon cold plate 200 by the one or more recesses on the mating side of each of first half plate 203 and second half plate 204. In some embodiments, the one or more coolant inlet ports may be hexagonal shaped, and the one or more coolant outlet ports may also be hexagonal shaped. Referring to FIGS. 4A and 4B, the edge of silicon cold plate 200 that faces the reader includes a coolant inlet port and a coolant outlet port. A coolant outlet connector 401 may be accommodated by, received in, mounted on or otherwise coupled to the coolant outlet port. A coolant inlet connector 402 may be accommodated by, received in, mounted on or otherwise coupled to the coolant inlet port. In various other embodiments in accordance with the present disclosure (not shown), one or more other edges of silicon cold plate 200 may additionally include one or more coolant inlet ports and/or one or more coolant outlet ports. Referring to FIG. 4B, in which the mating side of second half plate 204 is visible, the mating side of second half plate 204 includes multiple etched silicon coolant channels 430 and coolant flow directors 431.

In the example shown in FIGS. 4A and 4B, the carry side of first half plate 203 includes electrical and thermal patterns or connections 206. A heat-generating device 100 may be electrically and thermally bonded to and disposed on electrical and thermal patterns or connections 206 with pads, ball-bumps or pins of heat-generating device 100 (not shown) in contact and connected to electrical and thermal patterns or connections 206. Heat-generating device 100 may be an IC chip with high thermal flux. Electrical and thermal patterns or connections 206 are electrically and thermally conductive, and may be formed on the carry side of first half plate 203 by electroplating or metal deposition. Heat-generating device 100, as an IC chip or an electronic device, may receive electrical power through as well as dissipate heat through electrical and thermal patterns or connections 206.

Apparatus 40 may also include a substrate 410. In some embodiments, substrate 410 may be a printed circuit board (PCB). Substrate 410 may have a number of IC chips (such as IC chips 411, 413 and 414 shown in FIGS. 4A and 4B) and an electrical connector 412 disposed on a first primary side thereof. Each of heat-generating device 100 and IC chips 411, 413 and 414 may be electrically connected to electrical connector 412. Electrical connector 412 may be configured to electrically connect heat-generating device 100 and/or at least one of IC chips 411, 413 and 414 to an external device. Substrate 410 may include an opening or through-hole (e.g., in or around a central portion thereof) configured to accommodate heat-generating device 100 when substrate 410 is disposed on the carry side of first half plate 203 of silicon cold plate 200. The carry side of first half plate 203 of silicon cold plate 200 is electrically and thermally bonded a second primary side of substrate 410, which is opposite to the first primary side thereof, through contact points and circuits (e.g., electrical and thermal patterns or connections 206) on the carry side of first half plate 203.

It is noteworthy that, although one substrate (namely substrate 410) is shown to be disposed on one side of silicon cold plate 200 in FIGS. 4A and 4B, in various other embodiments an additional substrate similar to substrate 410 may be disposed on the other side of silicon cold plate 200 with corresponding heat-generating device/IC chips similar to heat-generating device 100 and IC chips 411, 413 and 414. That is, a single silicon cold plate 200 may be sandwiched by two substrates 410 on both sides. This design may be very effective in a compact form factor and may help even out thermal stress imposed on the silicon cold plate 200 given that both sides of the silicon cold plate 200 may be exposed to similar thermal stress.

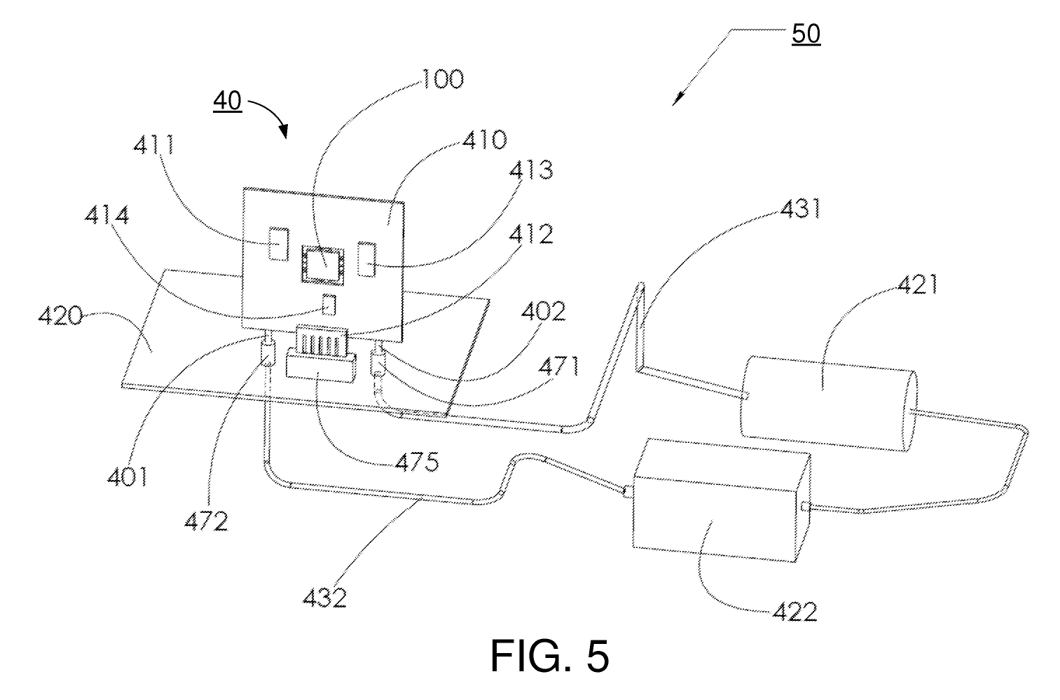

FIG. 5 is a diagram of a system 50 incorporating apparatus 40 shown in FIGS. 4A and 4B. As shown in FIG. 5, system 50 may include a motherboard or rack backplate 420 with a mating electrical connector 475 thereon. Apparatus 40 may be electrically connected to motherboard or rack backplate 420 with electrical connector 412 connected to mating electrical connector 475. System 50 may also include a pump 421, a reservoir tank or accumulator 422, coolant inlet tubing 431, coolant outlet tubing 432, a coolant inlet coupling or adapter 471 connected to coolant inlet connector 402, and a coolant outlet coupling or adapter 472 connected to coolant outlet connector 401. A coolant (not shown), which may be a liquid or gas, may be pumped by pump 421 to motherboard or rack backplane 420 to flow into silicon cold plate 200 of apparatus 40, through coolant inlet coupling or adapter 471 connected to coolant inlet connector 402, and out of silicon cold plate 200, through coolant outlet coupling or adapter 472 connected to coolant outlet connector 401, returning to reservoir tank or accumulator 422. As the coolant flows through silicon cold plate 200, which is thermally connected to heat-generating device 100 and substrate 410 on which IC chips 411, 413 and 414 are disposed, the coolant helps remove heat from heat-generating device 100 and substrate 410 (as well as IC chips 411, 413 and 414).

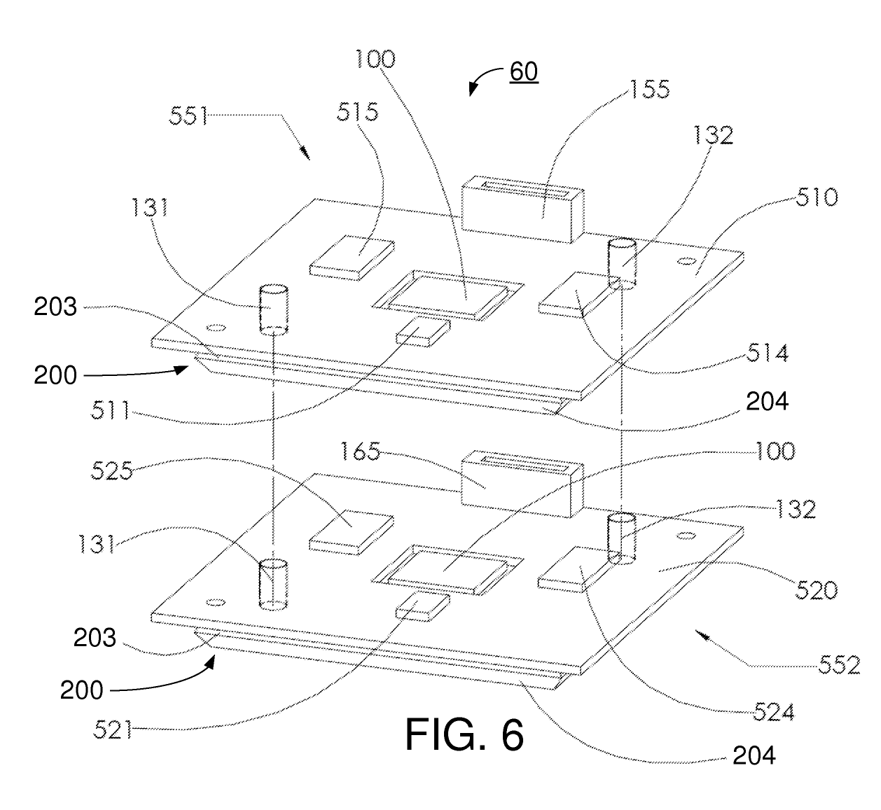

FIG. 6 is a diagram of an apparatus 60 in accordance with an embodiment of the present disclosure. As shown in FIG. 6, apparatus 60 may include an assembly of multiple modules of silicon cold plate and corresponding substrate (e.g., PCBs) stacked together. Apparatus 60 may be a solution of heat removal for high thermal flux circuitry in large system designs. Each module of silicon cold plate and corresponding substrate may be similar or identical to apparatus 10 and/or apparatus 20 described previously. For instance, in the example shown in FIG. 6, apparatus 60 may include a first module 551 and a second module 552.

First module 551 may include a silicon cold plate 200 with a heat-generating device 100 and a substrate 510 disposed thereon. In some embodiments, substrate 510 may be a PCB. Substrate 510 may have a number of IC chips (such as IC chips 511, 514 and 515 shown in FIG. 6) and a connector 155 disposed on a first primary side thereof. Connector 155 may be configured to electrically connect heat-generating device 100 and/or at least one of IC chips 511, 514 and 515 to an external device. Connector 155 may also be configured to mechanically connect substrate 510 to another substrate. Substrate 510 may include an opening (e.g., in or around a central portion thereof) configured to accommodate heat-generating device 100 when substrate 510 is disposed on the carry side of first half plate 203 of silicon cold plate 200. Substrate 510 may also include coolant flow connectors 131 and 132 (e.g., one for incoming path and the other for outgoing path of a coolant) connected to corresponding through holes on substrate 510. The carry side of first half plate 203 of silicon cold plate 200 is electrically and thermally bonded a second primary side of substrate 510, which is opposite to the first primary side thereof, through contact points and circuits (e.g., electrical and thermal patterns or connections 206) on the carry side of first half plate 203.

Second module 552 may include a silicon cold plate 200 with a heat-generating device 100 and a substrate 520 disposed thereon. In some embodiments, substrate 520 may be a PCB. Substrate 52 may have a number of IC chips (such as IC chips 521, 524 and 525 shown in FIG. 6) and a connector 165 disposed on a first primary side thereof. Connector 165 may be configured to electrically connect heat-generating device 100 and/or at least one of IC chips 521, 524 and 525 to an external device. Connector 165 may also be configured to mechanically stack substrate 510 onto substrate 520. That is, connector 165 may be mechanically (and electrically) connected to connector 155 so as to stack first module 551 on second module 522. Substrate 520 may include an opening (e.g., in or around a central portion thereof) configured to accommodate heat-generating device 100 when substrate 520 is disposed on the carry side of first half plate 203 of silicon cold plate 200. Substrate 520 may also include coolant flow connectors 131 and 132 (e.g., one for incoming path and the other for outgoing path of a coolant) connected to corresponding through holes on substrate 520. Coolant flow connectors 131 and 132 of second module 552 may be connected to coolant flow connectors 131 and 132, respectively, of first module 521 when first module 551 is stacked on second module 552. The carry side of first half plate 203 of silicon cold plate 200 is electrically and thermally bonded a second primary side of substrate 520, which is opposite to the first primary side thereof, through contact points and circuits (e.g., electrical and thermal patterns or connections 206) on the carry side of first half plate 203.

It is noteworthy that, although two modules (namely first module 551 and second module 552) are illustrated in the example shown in FIG. 6, a greater quantity of modules may be utilized in various other embodiments in accordance with the present disclosure.

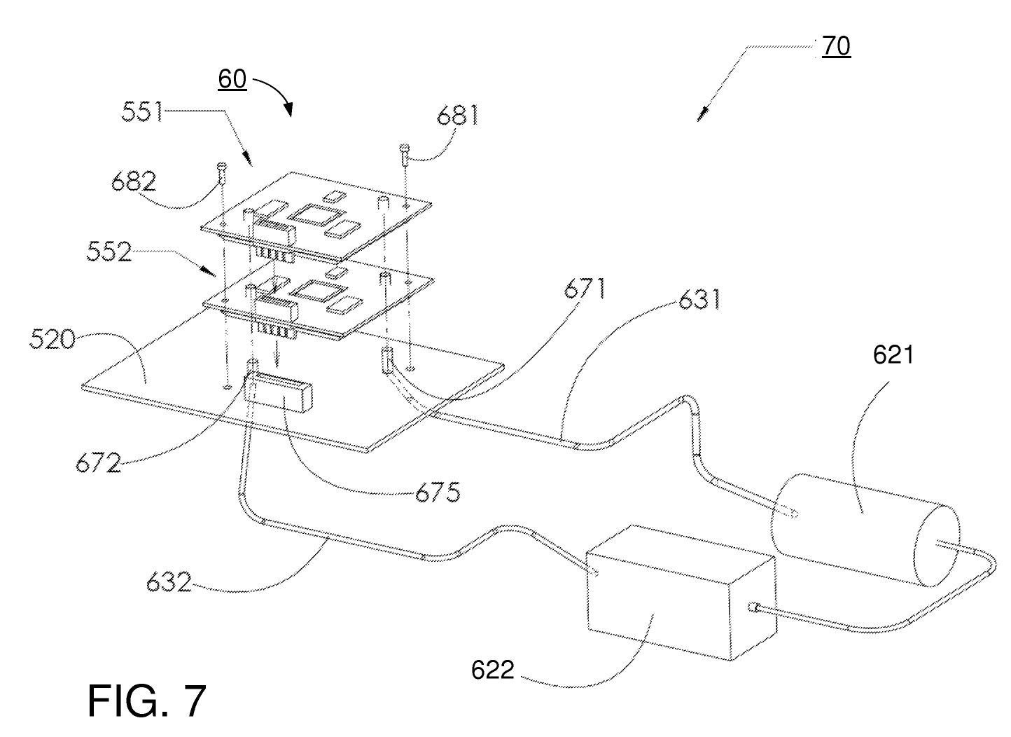

FIG. 7 is a diagram of a system 70 incorporating apparatus 60 shown in FIG. 6. As shown in FIG. 7, system 70 may include a motherboard or rack backplate 520 with a mating connector 675 thereon. Apparatus 60 may be mechanically and electrically connected to motherboard or rack backplate 520 with connector 522 connected to mating connector 675. System 70 may also include a pump 621, a reservoir tank or accumulator 622, coolant inlet tubing 631, coolant outlet tubing 632, a coolant inlet coupling or adapter 671, and a coolant outlet coupling or adapter 672. A coolant (not shown), which may be a liquid or gas, may be pumped by pump 621 to motherboard or rack backplane 520 to flow into silicon cold plates 200 of apparatus 60, through coolant inlet coupling or adapter 671, and out of the silicon cold plate 200s of apparatus 60, through coolant outlet coupling or adapter 672, returning to reservoir tank or accumulator 622. As the coolant flows through the silicon cold plates 200 of apparatus 60, which are thermally connected to heat-generating devices 100, substrate 510 on which IC chips 511, 514 and 515 are disposed, and substrate 520 on which IC chips 521, 524 and 524 are disposed, the coolant helps remove heat from heat-generating devices 100, substrate 510 and substrate 520 (as well as IC chips 511, 514, 515, 521, 524 and 525).

It is noteworthy that, although two modules (namely first module 551 and second module 552) are illustrated in the example shown in FIG. 7, a greater quantity of modules may be utilized in various other embodiments in accordance with the present disclosure.

### Highlight of Select Features

In view of the above, select features in accordance with the present disclosure are highlighted below.

An apparatus may include a silicon plate, one or more electrical and thermal connections, and a heat-generating device. The silicon plate may include a first side and a second side opposite the first side, a plurality of edges between the first side and the second side, one or more internal coolant flow channels therein, one or more coolant inlet ports disposed on one or more of the edges and configured to allow a coolant to flow into the one or more internal coolant flow channels, and one or more coolant outlet ports disposed on one or more of the edges and configured to allow the coolant to flow out of the one or more internal coolant flow channels. The one or more electrical and thermal connections may be disposed on the first side of the silicon plate. The heat-generating device may be disposed on the one or more electrical and thermal connections.

In some implementations, the heat-generating device may include an IC chip.

In some implementations, at least one of the one or more coolant inlet ports and the one or more coolant outlet ports may include a hexagonal-shaped port.

In some implementations, the silicon plate may include a first half plate and a second half plate. Each of the first half plate and the second half plate may include a mating side, a carry side opposite the mating side, and a plurality of edges between the mating side and the carry side. The first half plate and the second half plate may be bonded together with the mating side of the first half plate and the mating side of the second half plate facing each other.

In some implementations, at least one of the edges of the first half plate or the second half plate may include a beveled edge.

In some implementations, the apparatus may also include one or more pins electrically connected to the electrical and thermal connections. The one or more pins may be configured to accommodate an electrical connection between the heat-generating device and an external device.

In some implementations, the apparatus may also include a substrate disposed on the first side of the silicon plate. The substrate may include a through-hole configured to accommodate the heat-generating device when the substrate is disposed on the first side of the silicon plate.

In some implementations, the substrate may include a PCB.

In some implementations, the apparatus may also include one or more IC chips disposed on the substrate. The apparatus may additionally include an electrical connector disposed on the substrate. The electrical connector may be electrically connected to at least one of the heat-generating device and the one or more IC chips.

In some implementations, the apparatus may further include a board, a mating electrical connector disposed on the board and configured to electrically connect to the electrical connector, fittings connected to the one or more coolant inlet ports and the one or more coolant outlet ports, a pump configured to pump the coolant through the one or more coolant flow channels of the silicon plate, a reservoir tank configured to store the coolant, and tubes configured to connect the pump to the reservoir tank, connect the pump to the one or more coolant inlet ports, and connect the reservoir tank to the one or more coolant outlet ports.

Another apparatus may include a first module and a second module. The first module may include a first silicon plate, one or more first electrical and thermal connections, and a first heat-generating device. The first silicon plate may include a first side and a second side opposite the first side, a plurality of edges between the first side and the second side, one or more internal coolant flow channels therein, one or more coolant inlet ports disposed on one or more of the edges and configured to allow a coolant to flow into the one or more internal coolant flow channels, and one or more coolant outlet ports disposed on one or more of the edges and configured to allow the coolant to flow out of the one or more internal coolant flow channels. The one or more first electrical and thermal connections may be disposed on the first side of the first silicon plate. The first heat-generating device may be disposed on the one or more first electrical and thermal connections. The second module may include a second silicon plate, one or more second electrical and thermal connections, and a second heat-generating device. The second silicon plate may include a first side and a second side opposite the first side, a plurality of edges between the first side and the second side, one or more internal coolant flow channels therein, one or more coolant inlet ports disposed on one or more of the edges and configured to allow the coolant to flow into the one or more internal coolant flow channels, and one or more coolant outlet ports disposed on one or more of the edges and configured to allow the coolant to flow out of the one or more internal coolant flow channels. The one or more second electrical and thermal connections may be disposed on the first side of the second silicon plate. The second heat-generating device may be disposed on the one or more second electrical and thermal connections.

In some implementations, each of the first heat-generating device and the second heat-generating device may include an IC chip.

In some implementations, at least one of the one or more coolant inlet ports and the one or more coolant outlet ports of each of the first silicon plate and the second silicon plate may include a hexagonal-shaped port.

In some implementations, the first silicon plate may include a first half plate and a second half plate. Each of the first half plate and the second half plate may include a mating side, a carry side opposite the mating side, and a plurality of edges between the mating side and the carry side. The first half plate and the second half plate may be bonded together with the mating side of the first half plate and the mating side of the second half plate facing each other.

In some implementations, at least one of the edges of the first half plate or the second half plate of the first silicon plate may include a beveled edge.

In some implementations, the apparatus may also include one or more pins electrically connected to the first electrical and thermal connections. The one or more pins may be configured to accommodate an electrical connection between the first heat-generating device and an external device.

In some implementations, the apparatus may also include a first substrate disposed on the first side of the first silicon plate and a second substrate disposed on the first side of the second silicon plate. The first substrate may include a through-hole configured to accommodate the first heat-generating device when the first substrate is disposed on the first side of the first silicon plate. The second substrate may include a through-hole configured to accommodate the second heat-generating device when the second substrate is disposed on the first side of the second silicon plate.

In some implementations, each of the first substrate and the second substrate may include a PCB.

In some implementations, the apparatus may also include one or more first IC chips disposed on the first substrate, one or more second IC chips disposed on the second substrate, a first electrical connector disposed on the first substrate, and a second electrical connector disposed on the second substrate. The first electrical connector may be electrically connected to at least one of the first heat-generating device and the one or more first IC chips. The second electrical connector may be electrically connected to at least one of the second heat second and the one or more second IC chips. The first module and the second module may be stacked together with the first electrical connector and the second electrical connector mechanically and electrically connected together.

In some implementations, the apparatus may further include a board, a mating electrical connector disposed on the board and configured to electrically connect to the second electrical connector, fittings connected to the one or more coolant inlet ports and the one or more coolant outlet ports of the second silicon plate of the second module, a pump configured to pump the coolant through the one or more coolant flow channels of the first silicon plate of the first module and the one or more coolant flow channels of the second silicon plate of the second module, a reservoir tank configured to store the coolant, and tubes configured to connect the pump to the reservoir tank, connect the pump to the one or more coolant inlet ports, and connect the reservoir tank to the one or more coolant outlet ports.

### Additional Notes and Conclusion

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An apparatus, comprising:
a silicon plate comprising:
a first side and a second side opposite the first side;
a plurality of edges between the first side and the second side;
one or more internal coolant flow channels therein;
one or more coolant inlet ports disposed on one or more of the edges and configured to allow a coolant to flow into the one or more internal coolant flow channels; and
one or more coolant outlet ports disposed on one or more of the edges and configured to allow the coolant to flow out of the one or more internal coolant flow channels;
one or more electrical and thermal connections disposed on the first side of the silicon plate; and
a heat-generating device disposed on the one or more electrical and thermal connections.

2. The apparatus of claim 1, wherein the heat-generating device comprises an integrated-circuit (IC) chip.

3. The apparatus of claim 1, wherein at least one of the one or more coolant inlet ports and the one or more coolant outlet ports comprises a hexagonal-shaped port.

4. The apparatus of claim 1, wherein the silicon plate comprises a first half plate and a second half plate, wherein each of the first half plate and the second half plate comprises a mating side, a carry side opposite the mating side, and a plurality of edges between the mating side and the carry side, and wherein the first half plate and the second half plate are bonded together with the mating side of the first half plate and the mating side of the second half plate facing each other.

5. The apparatus of claim 4, wherein at least one of the edges of the first half plate or the second half plate comprises a beveled edge.

6. The apparatus of claim 1, further comprising:
one or more pins electrically connected to the electrical and thermal connections, the one or more pins configured to accommodate an electrical connection between the heat-generating device and an external device.

7. The apparatus of claim 1, further comprising:
a substrate disposed on the first side of the silicon plate, the substrate comprising a through-hole configured to accommodate the heat-generating device when the substrate is disposed on the first side of the silicon plate.

8. The apparatus of claim 7, wherein the substrate comprises a printed circuit board (PCB).

9. The apparatus of claim 7, further comprising:
one or more integrated-circuit (IC) chips disposed on the substrate; and
an electrical connector disposed on the substrate, the electrical connector electrically connected to at least one of the heat-generating device and the one or more IC chips.

10. The apparatus of claim 9, further comprising:
a board;
a mating electrical connector disposed on the board, the mating electrical connector configured to electrically connect to the electrical connector;
fittings connected to the one or more coolant inlet ports and the one or more coolant outlet ports;
a pump configured to pump the coolant through the one or more coolant flow channels of the silicon plate;
a reservoir tank configured to store the coolant; and
tubes configured to connect the pump to the reservoir tank, connect the pump to the one or more coolant inlet ports, and connect the reservoir tank to the one or more coolant outlet ports.

11. An apparatus, comprising:
a first module comprising:
a first silicon plate comprising:
a first side and a second side opposite the first side;
a plurality of edges between the first side and the second side;
one or more internal coolant flow channels therein;
one or more coolant inlet ports disposed on one or more of the edges and configured to allow a coolant to flow into the one or more internal coolant flow channels; and
one or more coolant outlet ports disposed on one or more of the edges and configured to allow the coolant to flow out of the one or more internal coolant flow channels;
one or more first electrical and thermal connections disposed on the first side of the first silicon plate; and
a first heat-generating device disposed on the one or more first electrical and thermal connections; and
a second module comprising:
a second silicon plate comprising:
a first side and a second side opposite the first side;
a plurality of edges between the first side and the second side;
one or more internal coolant flow channels therein;
one or more coolant inlet ports disposed on one or more of the edges and configured to allow the coolant to flow into the one or more internal coolant flow channels; and
one or more coolant outlet ports disposed on one or more of the edges and configured to allow the coolant to flow out of the one or more internal coolant flow channels;
one or more second electrical and thermal connections disposed on the first side of the second silicon plate; and
a second heat-generating device disposed on the one or more second electrical and thermal connections.

12. The apparatus of claim 11, wherein each of the first heat-generating device and the second heat-generating device comprises an integrated-circuit (IC) chip.

13. The apparatus of claim 11, wherein at least one of the one or more coolant inlet ports and the one or more coolant outlet ports of each of the first silicon plate and the second silicon plate comprises a hexagonal-shaped port.

14. The apparatus of claim 11, wherein the first silicon plate comprises a first half plate and a second half plate, wherein each of the first half plate and the second half plate comprises a mating side, a carry side opposite the mating side, and a plurality of edges between the mating side and the carry side, and wherein the first half plate and the second half plate are bonded together with the mating side of the first half plate and the mating side of the second half plate facing each other.

15. The apparatus of claim 4, wherein at least one of the edges of the first half plate or the second half plate of the first silicon plate comprises a beveled edge.

16. The apparatus of claim 11, further comprising:
one or more pins electrically connected to the first electrical and thermal connections, the one or more pins configured to accommodate an electrical connection between the first heat-generating device and an external device.

17. The apparatus of claim 11, further comprising:
a first substrate disposed on the first side of the first silicon plate, the first substrate comprising a through-hole configured to accommodate the first heat-generating device when the first substrate is disposed on the first side of the first silicon plate; and
a second substrate disposed on the first side of the second silicon plate, the second substrate comprising a through-hole configured to accommodate the second heat-generating device when the second substrate is disposed on the first side of the second silicon plate.

18. The apparatus of claim 17, wherein each of the first substrate and the second substrate comprises a printed circuit board (PCB).

19. The apparatus of claim 17, further comprising:
one or more first integrated-circuit (IC) chips disposed on the first substrate;
one or more second IC chips disposed on the second substrate;
a first electrical connector disposed on the first substrate, the first electrical connector electrically connected to at least one of the first heat-generating device and the one or more first IC chips; and
a second electrical connector disposed on the second substrate, the second electrical connector electrically connected to at least one of the second heat second and the one or more second IC chips,
wherein the first module and the second module are stacked together with the first electrical connector and the second electrical connector mechanically and electrically connected together.

20. The apparatus of claim 19, further comprising:
a board;
a mating electrical connector disposed on the board, the mating electrical connector configured to electrically connect to the second electrical connector;
fittings connected to the one or more coolant inlet ports and the one or more coolant outlet ports of the second silicon plate of the second module;
a pump configured to pump the coolant through the one or more coolant flow channels of the first silicon plate of the first module and the one or more coolant flow channels of the second silicon plate of the second module;
a reservoir tank configured to store the coolant; and
tubes configured to connect the pump to the reservoir tank, connect the pump to the one or more coolant inlet ports, and connect the reservoir tank to the one or more coolant outlet ports.
